(19) United States
(12) Patent Application Publication
(10) Pub. No.: US 2004/0238364 A1
(43) Pub. Date: Dec. 2, 2004

(54) Modular gel-strip carrier element

(76) Inventors: Owe Salven, Uppsala (SE); Ingmar Olsson, Uppsala (SE); Bengt Bjellgvist, Uppsala (SE)

Correspondence Address: AMERSHAM BIOSCIENCES, PATENT DEPARTMENT, 800 CENTENNIAL AVENUE, PISCATAWAY, NJ, 08855, US

(21) Appl. No.: 10/482,712

(22) PCT Filed: Jul. 9, 2002
(86) PCT No.: PCT/EP02/07626

(30) Foreign Application Priority Data
Jul. 13, 2001 (GB) 0117030.7
Jul. 31, 2001 (GB) 0118613.9

(51) Int. Cl. G01R 1/00; C02F 1/40

(52) U.S. Cl. 204/606

(57) ABSTRACT

A carrier module for holding a gel-strip in heat transferring contact with the surface of a cooling plate or a Peltier plate in an electrophoretic separation process, comprising a carrier member (1,10) formed in a plastic material for disposable use; the carrier member having a top plane formed with at least one elongate channel (2) for receiving the gel-strip in longitudinal contact with a bottom portion (5) of the channel, the carrier member being molded to have a shell-formed structure wherein said channel is depressed from the top plane of the shell structure so as to be able to rest with its bottom in contact with the cooling plate surface.

### TECHNICAL FIELD

The present invention relates to a modular carrier element for a gel-strip. More precisely, the invention refers to a disposable, plastic gel-strip carrier element for use in the electrophoretic separation of proteins.

### BACKGROUND AND PRIOR ART

Electrophoretic separation as herein referred to is used for the purification of proteins or for the separation of protein mixtures, e.g., through the migration of proteins in a medium under the influence of an electric field. Conventionally, the medium is an elongate IPG gel-strip (immobilized pH gradient strip) that is carried by a strip holder which can rest on a cooling surface of a cooling plate—see WO 98 57161. The cooling plate, or Peltier plate where appropriate, is arranged in an instrument designed for controlling the temperature of the gel, and for applying a voltage that causes the migration of proteins in the gel in a first dimension of a two-dimensional separation process.

In the separation process, it is essential to control and stabilize the temperature of the gel during the process. In order to provide for effective heat transfer from the gel, the gel-strip holder is typically formed in a ceramic material having high thermal conductivity, such as aluminum-oxide. The cost for producing ceramic gel-strip holders however necessitates a repeated use of the gel-strip holder.

In the course of finding cost effective separation processes, it is a major drawback and a problem to prepare the ceramic gel-strip holder for repeated analysis. Thus, there is a need and desire for a low cost and disposable gel-strip holder, reducing the manual work involved in the laboratory procedures. In order to eliminate said drawbacks of conventional gel-strip holders, and in order to meet the need and desire for a disposable gel-strip holder, the present invention primarily aims at providing a gel-strip carrier element of low cost material and production while securing a capacity for controlling the temperature in the gel during the separation process.

In a second aspect of the invention there is provided a disposable, ready to use gel-strip carrier element that is prepared with a gel-strip which is preserved in a storage condition by the carrier element.

In yet another aspect of the invention, there is provided a gel-strip carrier element that is designed to promote an automated handling of the gel in a separation process of the first dimension by being structured for a disposable use. In a further aspect of the invention, there is provided a disposable gel-strip carrier element of modular design, with a capacity to carry a plurality of gel-strips in an electrophoretic separation process.

### SUMMARY OF THE INVENTION

The above objects and desires are met in a gel-strip carrier element as defined in the attached set of claims. Briefly, the present invention suggests a disposable gel-strip carrier element or module preferably produced from a plastic material and which is structured for an effective heat transfer from the gel-strip to the cooling plate.. The carrier element preferably is molded to have a shell formed structure, such that the gel is separated from the cooling plate surface by a material section of limited or reduced thickness. Further aspects of the invention are defined in the subclaims.

### DRAWINGS

Below, the invention is described more in detail, reference being made to the accompanying drawings wherein:

FIG. 1 is a top perspective view of a gel-strip carrier element in accordance with the present invention;

FIG. 2 is a bottom perspective view of the carrier element of FIG. 1;

FIG. 3 shows the sectional profile of the carrier element of FIGS. 1 and 2, resting onto the surface of a cooling plate;

FIG. 4 is a top perspective view showing a gel-strip carrier module of the invention formed with a plurality of strip holders;

FIG. 5 is a top perspective view showing a carrier element that is prepared with a gel-strip under a sealing cover;

FIG. 6 schematically illustrates a bar designed for applying an electric field over the gel-strip, and

FIG. 7 schematically illustrates a lid designed for applying an electric field over the gel-strip.

### DETAILED DESCRIPTION OF THE INVENTION

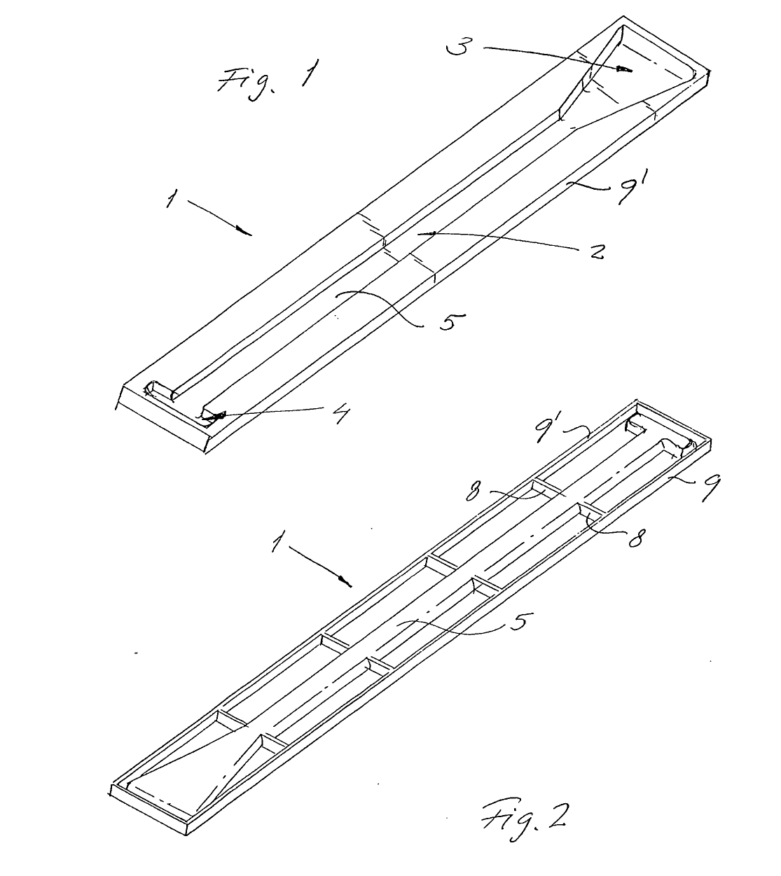

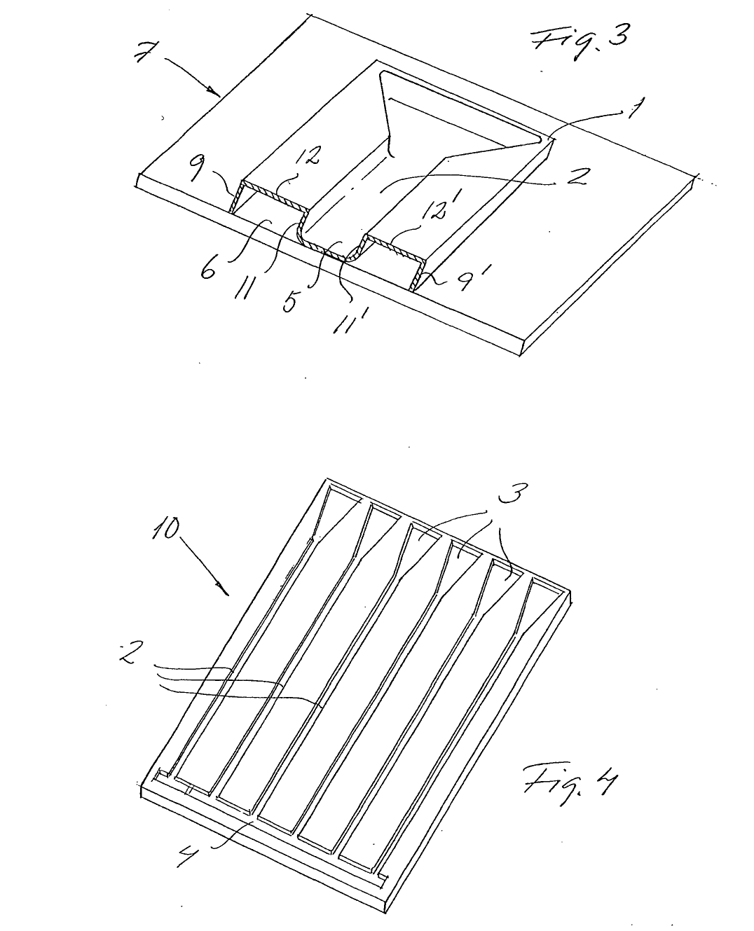

With reference to FIGS. 1 and 2, a carrier element 1 for a gel-strip (not shown) is formed with an elongate channel 2 in a top plane of the carrier element. In one end thereof, the channel 2 adjoins a basin 3. In the opposite end, the channel 2 optionally adjoins an overflow cavity 4. The channel 2 is formed to have a continuous sectional profile between the basin and the overflow cavity for receiving a gel-strip in longitudinal contact with a bottom portion 5 of the channel 2. The basin 3 is formed to receive a sample in contact with the gel-strip end, and may advantageously have a tapering sectional width towards the end of the channel 2. The over flow cavity 4 is formed to receive excessive liquid from the strip, e.g., and may advantageously be formed to extend transversely in the opposite end of the channel 2.

As best seen in FIG. 2, the channel 2, the basin 3 and the overflow cavity 4 are depressed from the top plane of the carrier element 1 such that a substantially planar bottom portion 5 is formed, joining the three cavities at a substantially continuous height below the top plane. In use, the carrier element 1 is positioned to rest with the bottom portion 5 in, preferably substantially continuous, longitudinal contact with a top surface 6 of a cooling plate 7, as illustrated in FIG. 3.

Referring now to FIGS. 2 and 3, the carrier element 1 is designed to have a shell formed structure. In this context, the expression “shell formed structure” should be understood as defining a thin-walled, hollow body that separates the gel-strip from the cooling plate surface by a wall section having only a limited or reduced thickness in order to enhance the cooling effect of the plate 7. The sectional profile of the shell structured body of carrier element 1 is further explained below.

### BEST MODE OF OPERATION

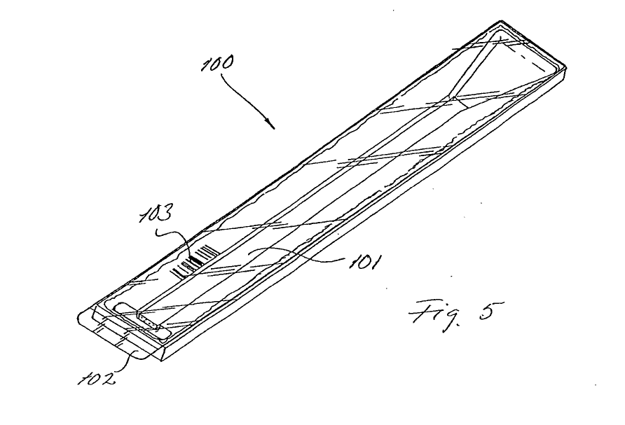

In the best mode of operation, the channel 2, basin 3 and optionally the overflow cavity 4 are formed within the outer margins of a preferably four-sided, parallelepiped body, the body preferably being open towards the cooling plate surface when it is being used. Advantageous embodiments include a modular design, incorporating two, three or more channels 2 arranged side by side and integrally formed as depressions made in the top plane of a carrier module 10, as shown in FIG. 4. On the bottom side, as seen in FIG. 2, the shell structured body preferably comprises transverse ribs 8 connecting the channel/channels 2 to longitudinal side panels 9,9′ of the body. The ribs 8 are provided as stabilizers to counteract warping of the shell structure, and thus ensuring a rigid structure that promotes heat transferring contact between the whole length of the channel bottom portion/portions 5 and the cooling plate surface when in use. The upper margins of the side panels 9,9′ are connected to the top plane, and the lower margins are level with the bottom of the channel/channels 2.

Alternatively, carrier elements 1 may be coupled to form a modular assembly by having mating coupling means (not shown) arranged on the outer sides of the longitudinal side panels 9,9′. Such coupling means may include snap-lock means, male and female slip-fit means or other suitable means, known per se.

As best seen in FIG. 3, the shell structured body typically has a castellated sectional profile. More exactly, the channel or channels 2 are formed with thin walled, longitudinal side portions 11,11′ depending from the top plane to extend in parallel between the side panels 9,9′. Thus in section through a channel 2, as seen from left to right in FIG. 3, the carrier element 1 is defined at least by the following wall elements:

a first upright side panel 9;

a first top plane portion 12 horizontally extended from the upper margin of the first side panel;

a first channel side portion 11 depending from the first top plane portion;

a channel bottom 5 horizontally connecting a lower margin of the first channel side portion with a lower margin of a second channel side portion 11′;

the second channel side portion rising to adjoin a second top plane portion 12′ that is horizontally connected to the upper margin of a second side panel 9′;

and the second side panel 9′ reaching down from the second top plane portion to terminate with its lower margin leveled with the lower margin of the first side panel 9 and the horizontal bottom portion 5.

Thus in a preferred embodiment the heights of the first upright side panel 9, the first channel side portion 11, the second channel side portion 11′ and the second channel side portion, are chosen so that when the carrier element of the present invention is placed on a flat surface the side panels 9, 9′ and the channel bottom are all in contact with this surface. In this way good cooling contact between the channel bottom 5 and a flat, underlying cooling surface may be achieved during use. Of course it is conceivable that a cooling surface could be arranged which projects up a distance X from a surface that is intended to support the side portions of a carrier element. In such a case it would be appropriate to provide a carrier element with a channel bottom that is raised a similar distance X (or less if a firmer contact with the cooling surface is desired) above the lower margins of the side portions of the carrier element. Similarly, if the cooling surface is recessed a distance Y in a side portion supporting surface, then the channel bottom of a carrier element may project below the plane of the lower margins of the side portions of the carrier element sufficiently far (i.e. at least a distance Y) so as to come into contact with the cooling surface.

In the modular design where two or more channels 2 are running in parallel and separated by the top plane portions between the side panels 9,9′, the castellated profile will be even more accentuated. Optionally, the longitudinal connections between the wall elements of the shell structured body may be angled, beveled or rounded, and the standing wall elements may be vertical, substantially vertical or slanting in a vertical plane. The wall thickness may be continuous and equal for all wall elements—alternatively, a reduced wall thickness down to approximately 1-2 mm, or even less, may be considered for the channel bottom 5 if appropriate with respect to the choice of material and production. Conceivable methods for molding a plastic carrier element 1 include injection molding, vacuum molding and blow molding.

The carrier element 1,10 may be produced at low cost by molding in a plastic material such as a polycarbonate or a polypropylene plastic, a ketone plastic (PEEK), or any other suitable plastic material thereby allowing a disposable use. The poor thermal conductivity of most plastic materials, as compared to aluminum-oxide or other ceramics, is compensated for by the thin channel bottom of the suggested shell structure of the carrier element. Thus, minimizing the thickness of the material section that separates the gel-strip from the cooling plate allows the implementation of a disposable material in a shell structure where heat accumulation can be effectively avoided.

In another aspect of the invention (see FIG. 5), there is suggested a disposable, ready to use gel-strip carrier element 100 that is prepared with a gel-strip 101 which is preserved in a storage condition by the carrier element 100. For this purpose, a substantially water-impermeable and vapor-impermeable cover 102 is detachably attached to the top plane of the carrier element 100. Preferably, the cover 102 is bonded near the outer margins about the top surface of the carrier element 100, and manually or mechanically ripped off when it is desired to exposing the gel-strip 101. The gel-strip may be stored in a dehydrated or a re-hydrated condition under the sealing cover 102, gel-side facing down towards the bottom of the elongate channel.

In use, the gel-strip carrier element 100 with re-hydrated gel-strip 101 promotes a rational laboratory work by simply ripping off the cover 102, adding a sample to the sample basin and placing the carrier element and gel-strip on the instrument. The few procedural steps may readily be automated, since the carrier element is disposable and requires only non-complex measures upon completion of the separation.

In yet another aspect of the invention, the carrier element is adapted for automated handling of gel-strips in electrophoretic separation of the first dimension. For this purpose, the carrier element is designed to cooperate with the gripper of a programmable/controllable mover mechanism. Supply storage of carrier elements with gel-strips ready for use is readily accomplished, due to the flat rectangular shape of a light weight and rigid carrier element, and also due to the thin seal that covers the gel-strip in a storing condition. If made by a molding process, structures for mechanical and/or frictional engagement with a mover mechanism may readily be integrated in the shell structured body of plastic material. Also, the smooth and planar surface of the top plane is well adapted to be engaged by a vacuum cup. Identification of individual gel-strips may be accomplished by applying a bar code identification 103 to the carrier module, for example, under the sealing cover, or by printing on the sealing cover for reading the identity of individual gel-strips in an automated assay procedure.

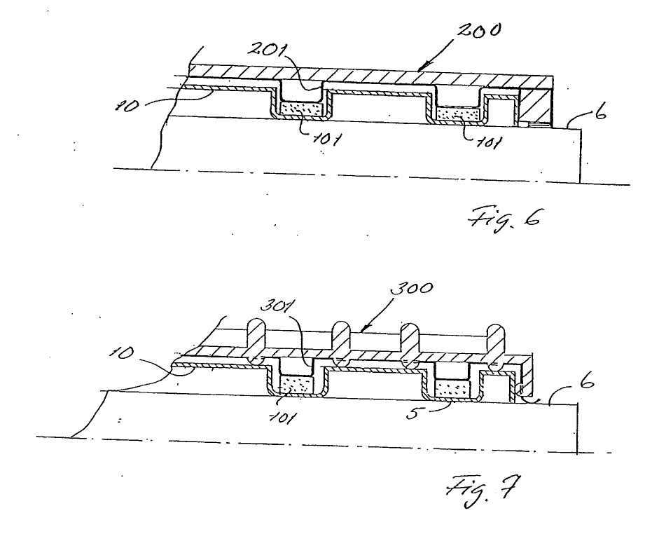

With reference to FIG. 6, a bar member 200 is illustrated for electrically connecting the gel-strips 101 in the carrier module 10 with the cooling plate. The connection bar 200 may advantageously be formed with arresting means or similar means for a snap-on attachment of the bar to the carrier module. Electric contact with the cooling plate or Peltier plate may be established by means of electrodes 201 that may also work as depressing means for fixation of the gel-strips, at both ends thereof.

Alternatively, see FIG. 7, a lid member 300 is suggested for electrically connecting the gel-strips with the Peltier plate. Electrodes 301 are supported on the lid. The lid 300 may advantageously be pivotally attached to the instrument, such that electric contact is established between the gel-strips and Peltier plate when the lid is pivoted to a closed position, covering the carrier module with the gel-strips received therein. The lid 300 is formed on the under side for applying a downward force on the carrier module in the closed position of the lid, in order to ensure a longitudinal contact between the channel bottom and the Peltier plate surface for optimal heat transport from the gel.

The bars 200, or the lid 300 in the closed position, electrically connect both ends of the gel-strip/gel-strips with the Peltier plate. In the case of a sample paper in the basin being placed in overlying contact with the gel-strip end, a bar 200 or the lid 300 preferably applies a downward force to the overlapping area for a firm contact between the sample and the gel.

The modular carrier element for disposable use as disclosed above provides a significant improvement in aspects of manual work savings and costs. Alternative designs may be considered within the scope of invention as defined in the attached set of claims.

1. A carrier module for holding a gel-strip in heat transferring contact with a cooling plate surface in an electrophoretic separation process, comprising:
a carrier member (1,10) formed in a plastic material;
the carrier member having a top plane formed with at least one elongate channel (2) for receiving a gel-strip in longitudinal contact with a bottom portion (5) of the channel;
said carrier member having a shell structure wherein said channel is depressed from the top plane of the shell structure.

2. The carrier module of claim 1, wherein said carrier member includes a four-sided, parallelepiped body having longitudinal side panels (9,9′), the upper margins of the side panels being connected to the top plane and the lower margins level with the bottom portion (5) of the channel (2).

3. The carrier module of claim 2, wherein said carrier member (1,10) includes a hollow body that is substantially open between said bottom portion (5) of the channel (2) and said side panels (9, 9′).

4. The carrier module of claim 2, wherein said carrier member is reinforced against warping by a framework of stabilizing members (8) integrally formed in the shell structure and connecting the channel (2) to the longitudinal side panels (9,9′) of the carrier module (1,10).

5. The carrier module of claim 1, wherein the channel (2) has a continuous sectional profile, one end of the channel adjoining a basin (3), the basin having a widening sectional width and being designed for receiving a sample, the other end of the channel terminating in an overflow cavity (4).

6. The carrier module of claim 1, wherein the plastic material is selected from the group consisting of polycarbonates and polypropylenes.

7. The carrier module of claim 1, wherein a dehydrated gel-strip is stored in the channel under a sealing, removable cover (102).

8. The carrier module of claim 1, wherein a rehydrated gel-strip is stored in the channel under a sealing, removable cover (102).

9. The carrier module of claim 7, wherein a bar code identification (103) is applied under the sealing cover, or printed on the sealing cover (102), for reading the identity of the individual gel-strip in an automated assay procedure.

10. The carrier module of claim 1, having mating coupling means arranged on the side panels (9,9′) for connecting to adjacent carrier modules (1,10).

11. The carrier module of claim 1, including at least the following wall elements:
a first upright side panel (9);
a first top plane portion (12) horizontally extended from the upper margin of the first side panel;
a first channel side portion (11) depending from the first top plane portion;
a channel bottom (5) horizontally connecting a lower margin of the first channel side portion with a lower margin of a second channel side portion (11′);
the second channel side portion rising to adjoin a second top plane portion (12′) that is horizontally connected to the upper margin of a second side panel (9′);
and the second side panel (9′) reaching down from the second top plane portion to terminate with its lower margin leveled with the lower margin of the first side panel (9) and the horizontal bottom portion (5).

12. A disposable gel-strip holder comprising a dehydrated/re-hydrated gel-strip secured under a removable cover (102), the cover sealing an elongate channel (2) that is designed to receive the gel-strip on a bottom portion (5) of the channel, the channel and gel-strip in one end adjoining a basin (3) designed to receive a sample paper in overlying contact with the end of the gel-strip, the other end of the channel and gel-strip adjoining an overflow cavity (4), said channel, said basin and said overflow cavity being integrally formed in a molded plastic carrier member (1,10) having a shell formed structure.
